(19) United States
(12) Patent Application Publication
(10) Pub. No.: US 2026/0215172 A1
(43) Pub. Date: Jul. 23, 2026

(54) NON-VOLATILE MEMORIES WITH VARIABLE RESISTANCE, RELATED METHODS AND ASSEMBLIES

(71) Applicants: Commissariat à l’Energie Atomique et aux Energies Alternatives, PARIS (FR); Centre National de la Recherche Scientifique, PARIS (FR); UNIVERSITE GRENOBLE ALPES, SAINT-MARTIN-D'HERES (FR); INSTITUT POLYTECHNIQUE DE GRENOBLE, GRENOBLE (FR)

(72) Inventors: Maxime CULOT, GRENOBLE CEDEX (FR); Théo FROTTIER, GRENOBLE CEDEX (FR); Williams SAVERO-TORRES, GRENOBLE CEDEX (FR); Aurélie KANDAZOGLOU, GRENOBLE CEDEX (FR); Salvatore TERESI, GRENOBLE CEDEX (FR); Paolo SGARRO, GRENOBLE CEDEX (FR); Manuel BIBES, GRENOBLE CEDEX (FR); Laurent VILA, GRENOBLE CEDEX (FR); Jean-Philippe ATTANE, GRENOBLE CEDEX (FR)

(21) Appl. No.: 19/431,561

(22) Filed: Dec. 23, 2025

(30) Foreign Application Priority Data
Dec. 24, 2024 (FR) 2415283

(51) Int. Cl. H10N 70/00; H10B 63/00

(52) U.S. Cl. CPC H10N 70/8828; H10B 63/84

(57) ABSTRACT

A memory comprising: a main conductive electrode forming a cathode; a secondary conductive electrode forming an anode; and a ferroelectric semiconducting layer forming an active layer, disposed between the cathode and the anode, the active layer having a ferroelectric bias having a plurality of stable states, the cathode forming a main contact with the active layer, the resistance of the main contact strictly monotonically varying as a function of the ferroelectric bias, the behaviour of the main contact forming, as a function of the ferroelectric bias: an ohmic contact for a first stable state of the plurality of stable states; and a Schottky contact for at least a second stable state of the plurality of stable states, the active layer being degenerate and having an energy band gap of less than 1.5 eV.

### TECHNICAL FIELD OF THE INVENTION

The technical field of the invention is that of variable resistance non-volatile memories. The technical field also relates to the methods for reading and manufacturing such memories, as well as the assembly of such memories as logic gates and arrays.

### TECHNOLOGICAL BACKGROUND OF THE INVENTION

Variable resistance memories, known as “memristors”, are capable of storing information at at least two levels. In some cases, these memristors are also capable of storing information that may have intermediate levels and/or performing logic operations. This latter type of memory is of particular interest in the implementation of new computation paradigms, such as analogue computation or neuromorphic computation.

Memristors include several families of memories, among which: magnetic memories and resistive memories. Magnetic memories allow information to be stored in a relative orientation of magnetic moments. Resistive memories allow information to be stored in the very resistance of one of the layers making them up. The change in resistance of the layer is induced, for example, by controlled breakdown of the layer or a phase change in the material making it up.

Among qualities of memristors, a memristor is expected to have a resistance variation, known as the “on/off ratio”, that is high enough to be easily and quickly measured, for example greater than 10², and that this on/off ratio can be measured even with a low read voltage. A memristor is also expected to have high endurance, greater than 10⁷ cycles.

The most common magnetic memories comprise Magnetic Tunnel Junctions (MTJs). MTJs generally have good endurance. However, they have a low on/off ratio, for example of a few units.

Resistive memories in which one of the layers undergoes a phase change or electrostatic breakdown generally have limited endurance. Other types of resistive memories, such as RRAM (Resistive Random Access Memory), also have limited endurance.

There is therefore a need for a variable resistance non-volatile memory with good endurance and a high on/off ratio, even at low read voltages.

Document [VAROTTO, Sara, NESSI, Luca, CECCHI, Stefano, et al. “Room-temperature ferroelectric switching of spin-to-charge conversion in germanium telluride.” Nature Electronics, 2021, vol. 4, no. 10, pp. 740-747.] discloses a ferroelectric memory. This memory comprises, on the one hand, a ferroelectric semiconducting layer of GeTe and, on the other hand, a conductive electrode of Ti. In addition to having stable ferroelectric bias, the GeTe layer is also intrinsically degenerate and has a low energy band gap, in the order of 0.7 eV. The contact between the electrode and the ferroelectric semiconducting layer forms a Schottky barrier the height and/or width of which varies as a function of the bias of the GeTe layer.

### SUMMARY OF THE INVENTION

The invention relates to a memory comprising:
a main conductive electrode forming a cathode;
a secondary conductive electrode forming an anode; and
a ferroelectric semiconducting layer forming an active layer, disposed between the cathode and the anode, the active layer having a ferroelectric bias (111) with a plurality of stable states,
   the cathode forming a main contact with the active layer, the resistance of the main contact strictly monotonically varying as a function of the ferroelectric bias, the behaviour of the main contact forming, as a function of the ferroelectric bias:
an ohmic contact for a first stable state of the plurality of stable states; and
a Schottky contact for at least a second stable state of the plurality of stable states,
   the active layer being degenerate and having an energy band gap of less than 1.5 eV.

The ferroelectric semiconducting layer allows information to be stored in a non-volatile manner by virtue of the ferroelectric bias, which can assume stable states. A measurement of the resistance of the main contact (for example, by measuring the total resistance between the cathode and the anode) makes it possible to determine in which stable state the ferroelectric bias is and, therefore, to read the information stored in the memory.

The change in behaviour (from ohmic to Schottky or vice versa) for the main contact ensures that the variation in resistance associated with two distinct states is large enough to be easily measurable.

As the ferroelectric semiconducting layer is degenerate and has a low band gap, it has low resistivity. The measurable resistance of the memory therefore mainly depends on the resistance of the main contact. Consequently, the ON/OFF ratio, defined as

$$\frac{{R}_{OFF}}{{R}_{O N}} ,$$

measured for two states or ferroelectric bias, where R_{ON} is the minimal resistance and R_{OFF} is the maximal resistance, is optimal, for example greater than 10² or even greater than 10⁵.

By virtue of the main contact, the memory can operate as a Schottky diode. The main conductive electrode forms, for example, a cathode of the Schottky diode, while the secondary conductive electrode forms an anode of the Schottky diode. The main memory can therefore be utilised in a circuit where a Schottky diode is useful. It can be utilised as a memory selector. The memory according to the invention is doubly advantageous in this type of circuit because the main contact can be made ohmic, allowing the equivalent Schottky diode to be “deactivated” by making it transparent.

Advantageously, the main contact also forms a Schottky contact for a third stable state of the plurality of stable states, the resistance of the main contact for the second stable state being lower than the resistance of the main contact for the third stable state.

Thus, the memory according to the invention can keep a Schottky behaviour, the resistance of which at the cathode varies as a function of the state in which bias of the ferroelectric semiconducting layer is. The leakage currents of an array integrating memories according to the invention are thus very low when the selected memory is electrically forward biased, so that the leakage currents correspond to paths passing through reverse biased memories and are therefore off.

Unlike memories in which a phase change, or a breakdown, is achieved in one of the layers, the memory according to the invention stores information by virtue of its electrical bias. Electrical bias can be switched a large number of times without inducing marked ageing. Therefore, like all ferroelectric memories, the memory according to the invention has very high endurance.

In addition to the characteristics just discussed in the preceding paragraphs, the memory according to the invention may have one or more of the following additional characteristics, considered individually or according to all technically possible combinations:

The main contact also forms a Schottky contact for a third stable state of the plurality of stable states, the resistance of the main contact for the second stable state being lower than the resistance of the main contact for the third stable state.

The main contact is formed at an interface between the active layer and the cathode, and in which, for each stable state, the ferroelectric bias has, at said interface, a component normal to said interface.

The anode forms an ohmic contact with the active layer, the resistance of the ohmic contact being independent of the ferroelectric bias.

The anode is semiconducting and forms a heterojunction or a homojunction with the active layer. In this case, the anode may comprise a stack of two semiconducting sub-layers, a first semiconducting sub-layer being undoped and a second semiconducting sub-layer being doped, the second semiconducting sub-layer forming a homojunction with the active layer.

The anode forms a secondary contact with the active layer, the resistance of the secondary contact strictly monotonically varying as a function of the ferroelectric bias, the resistance of the main contact as a function of the ferroelectric bias having a first monotony trend and the resistance of the secondary contact as a function of the ferroelectric bias having a second monotony trend, the two monotony trends being opposite to each other.

The stack comprises an insulating layer disposed between the active ferroelectric layer and the cathode or between the active layer and the anode.

According to an advantageous embodiment, the active ferroelectric layer is of GeTe. In this case, the active ferroelectric layer of GeTe may be co-doped with Bi and Cu, co-doped with Pb and Bi, or doped with Sn, Cu or Sb. According to this embodiment, the material of the cathode is, for example, selected from one of the following materials: Pt, Pd, Au, Fe. The material of the anode may be selected from one of the following materials: Ti, TiN, Ag.

The material of the anode is a semiconductor material so as to form a junction with the active layer such as a heterojunction or a homojunction. The junction may be a homojunction forming a PN-type junction.

The cathode is made from a material selected from: transition metals or transition metal alloys, post-transition metals or post-transition metal alloys, materials from columns I and II of the periodic table, or alloys of these materials.

The active layer is cylindrical and is wound around the cathode or around the anode.

The invention also relates to a method for reading a memory according to the invention, in which the Schottky contact is reverse biased. The reverse bias voltage applied to the main contact is advantageously strictly less than 0.1 V.

The invention also relates to a method for manufacturing a memory according to the invention, comprising:
minimising an energy volume density U:

$$U = αρ {( \frac{{I}_{r}}{S} )}^{2} {τ}_{r} + ( 1 - α ) \frac{{E}_{w}^{2}}{ρ} {τ}_{w}$$

with a resistivity ρ, a read/write ratio α, a write voltage E_{w}, a read current Iᵣ, a write time τ_{w}, and a read time τᵣ, and a surface area S, so as to obtain an optimal resistivity; and
forming a cathode, an anode and an active layer so that the active layer is disposed between the cathode and the anode and so that the active layer has ferroelectric bias having a plurality of stable states, and so that the cathode forms a main contact with optimal surface area S with the active layer, the resistance of the main contact strictly monotonically varying as a function of the ferroelectric bias, the behaviour of the main contact forming, as a function of the ferroelectric bias: an ohmic contact for a first stable state of the plurality of stable states; and a Schottky contact for at least a second stable state of the plurality of stable states, the active layer being degenerate and having an energy band gap of less than 1.5 eV.

The invention also relates to a logic gate comprising a first memory according to the invention and a second memory according to the invention, the first memory and the second memory being connected in series or in parallel.

Finally, the invention relates to a memory array comprising:
a plurality of memories according to the invention;
a plurality of conductive rows; and
a plurality of conductive columns,
   for each memory, the cathode is formed by one of the conductive rows and the anode is formed by one of the conductive columns.

In the array according to the invention, the conductive rows may be parallel to each other, the conductive columns may be parallel to each other, the conductive rows and conductive columns being arranged to intersect, each memory being disposed at an intersection between one of the conductive rows and one of the conductive columns.

The invention and its various applications will be better understood upon reading the following description and examining the accompanying figures.

### BRIEF DESCRIPTION OF THE FIGURES

The figures are set forth by way of indicating and in no way limiting purposes of the invention. Unless otherwise specified, a same element appearing in different figures has a single reference number.

FIG. 1 and FIG. 2 show two embodiments of a memory according to the invention.

FIG. 3 shows three additional embodiments of a memory according to the invention.

FIG. 4 shows three examples of current-voltage characteristics that can be measured for a memory according to the invention and for two memories according to prior art.

FIGS. 5, 6, 7, 8, 9 and 10 show five embodiments of an array according to the invention.

FIGS. 11 and 12 show two embodiments of a logic gate according to the invention.

### DETAILED DESCRIPTION

The aim of the invention is to improve storage of information, especially by providing high endurance and a high on/off ratio.

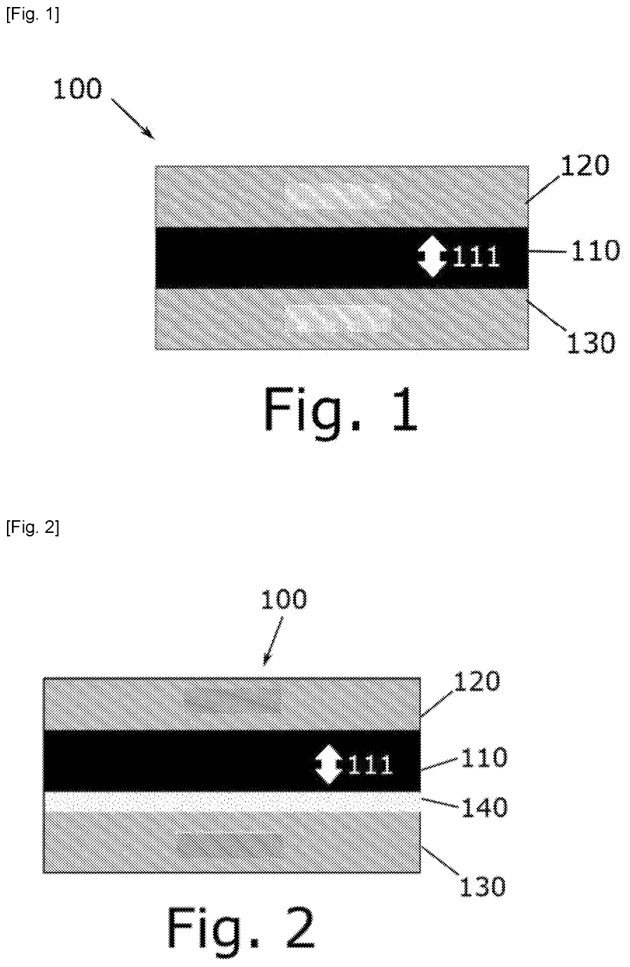

FIGS. 1 and 2 show two embodiments of a memory 100 according to the invention. The memory 100 comprises two conductive electrodes 120, 130 and a ferroelectric semiconducting layer 100.

The two conductive electrodes 120, 130 respectively form a main electrode 120 and a secondary electrode 130, respectively also called the cathode 120 and the anode 130. In the embodiments of FIGS. 1 and 2, the cathode 120 and the anode 130 extend in parallel to a plane and are superimposed on each other.

The ferroelectric semiconducting layer 110 forms a layer known as the “active layer”. It is designed to store information. The active layer 110 has a ferroelectric bias 111. This ferroelectric bias 111 corresponds, for example, to an average over a volume of the electrostatic dipole moments of the active layer 110.

The ferroelectric bias 111 may have at least two distinct stable states. Each stable state corresponds, for example, to a particular orientation of the ferroelectric bias 111 and/or a particular amplitude of the ferroelectric bias 111. From a microscopic point of view, the stable states correspond, for example, to particular configurations of the dipole moments forming the ferroelectric bias 111. When the ferroelectric bias 111 strictly has two stable states, it allows binary information to be stored. When it strictly has more than two stable states, for example three or more states, it allows multivalued information (that is, information that can take more than two states) to be stored. In an extreme case, when the ferroelectric bias 111 has a large number of stable states, it allows analogue information, that is, information that can take a value within a range of values, to be stored. It is, for example, a number between zero and one, or a standardised temperature.

According to the invention, the cathode 120 forms a first contact. This first contact is called the “main contact”. The contact can be formed by bringing the cathode 120 into direct contact with the active layer 110. This type of contact corresponds to a particular deformation of the energy bands of the active layer 110 (or even of the cathode when it is semiconducting) which can form an energy barrier at the interface between these two materials. The absence of a barrier at the interface (or a negligible barrier) forms a transparent (or quasi-transparent) contact, also called an “ohmic contact”, or a non-negligible resistance contact called a “Schottky contact”. An ohmic contact can be distinguished from a Schottky contact in that the ohmic contact has a linear I-V characteristic, while the Schottky contact has an exponential I-V characteristic.

The resistance at the interface between the active layer 110 and the cathode 120 (which will be referred to as the resistance of the main contact) depends on the presence or not of an energy barrier at this interface and on the height and/or width of this energy barrier. In the case of the invention, the resistance of the main contact is particular in that it is a function of the ferroelectric bias 111. Indeed, the energy bands in the active layer 110 and the cathode 120 are influenced by the electric field, such as that emanating from the ferroelectric bias. Thus, different bias states 111 (that is, different orientations or amplitudes of the associated electric field) correspond to different fields applied to the main contact, which:
completely erase the energy barrier (an ohmic contact is thus obtained); or
modulate the height and/or width of the energy barrier (a Schottky contact having different resistances for different biases, is thus obtained).

The invention provides that the resistance of the main contact is a strictly monotonic function of the ferroelectric bias 111. By “strictly monotonic”, it is meant that it has a derivative as a function of the ferroelectric bias 111 that is strictly positive or strictly negative. Stated differently, the resistance does not have two equal values for two distinct bias states. In practice, the monotony of the resistance can be obtained by means of the out-of-plane component of the ferroelectric bias 111. By “out-of-plane”, it is meant transverse to the interface formed between the active layer 110 and the cathode 120. This out-of-plane component may be non-zero. In order to ensure the presence of an out-of-plane component, the cathode 120 and the anode 130 are arranged so as to be aligned with a main bias axis of the active layer 110.

Thus, a measurement of the resistance of the main contact makes it possible to determine a projection of the state (that is, the orientation and/or amplitude) in which the ferroelectric bias 111 is situated. Stated differently, a measurement of the resistance of the main contact makes it possible to read the information stored in the memory 100. In one embodiment, the ferroelectric bias 111 can take at least two states, among which:
a first state corresponds to a measurable Schottky barrier (that is, having a significant resistance relative to the resistance of the active layer 110); and
a second state corresponds to an erased Schottky barrier corresponding to an ohmic contact (or a transparent contact, that is, the resistance of which is not significant relative to the resistance of the active layer 110).

By “significant resistance”, it is meant a resistance at least ten times greater than the reference resistance (here, the resistance of the active layer 110). Thus, switching the bias 111 between these two states allows the contact between the cathode 120 and the active layer 110 to change in nature, from a Schottky contact to an ohmic contact, or vice versa.

Storage of information by virtue of ferroelectric bias 111, and in particular switching from one state to another, does not require any structural change in the active layer 110. For example, it is not necessary to modify crystal arrangement of the active layer in order to switch from crystal to amorphous. Nor is it necessary to form a conductive filament within this active layer 110, for example by electrostatic breakdown. Thus, the mechanisms leading to premature ageing of the active layer 110, for a large number of cycles, are absent. The memory 100 according to the invention therefore provides good endurance.

Two states of the ferroelectric bias 111 correspond, for example, to two distinct resistances (due to the strict monotony of the resistance). The lowest resistance is denoted as R_{ON} and the highest resistance is denoted as R_{OFF}. In an extreme case, when the contact is ohmic, then the resistance R_{ON} is zero or almost zero. The memory 100 is then said to be “on”. In another extreme case, the Schottky barrier is enhanced by the influence of ferroelectric bias 11. The resistance R_{OFF} is then maximal. The memory 100 is then said to be “off”.

The “ON/OFF ratio” then corresponds to

$$α = \frac{{R}_{OFF}}{{R}_{O N}}$$

Thus, the lower the resistance R_{ON}, the higher the ON/OFF ratio.

Measurement of the ON/OFF ratio cannot be performed at the main contact alone. This measurement is carried out, for example, by measuring the total resistance between the cathode and the anode. This measurement therefore takes account of the resistance of the active layer 110. Thus, the total ON/OFF ratio becomes

$$α = \frac{{R}_{OFF} ∓ {R}_{110}}{{R}_{O N} + {R}_{110}}$$

Where R₁₁₀ is the total resistance of the active layer 110.

In order to reduce this resistance as much as possible so that it is negligible compared to the other amounts, the invention provides that the active layer 110 is degenerate and has a low energy band gap, in this case of less than 1.5 eV. In this way, the active layer 110 is conductive, even though it is semiconducting. It then has a low resistance R₁₁₀, maximising the total on/off ratio of the memory 100.

In one embodiment, the active layer 110 is of a GeTe alloy, which is a ferroelectric semiconductor having a gap of 0.7 eV and is intrinsically degenerate. The low resistance of the active layer 110 makes it possible, for example, to achieve an on/off ratio greater than 10⁴. The material In₂Se₃ is also a ferroelectric semiconductor material with a low gap (it has a gap of 1.35 eV). However, it is not intrinsically degenerate. Nevertheless, when chosen so as to be degenerate, it is a good candidate for forming the active layer 110.

The active layer 110 can be doped or co-doped to optimise energy consumption when reading or writing information therewithin, or to improve its ferroelectric properties. By “co-doped”, it is meant doped by means of two different dopant materials. For example, it can be doped with Sn, Cu or Sb. It can be co-doped with Bi and Cu or co-doped with Pb and Bi. The active layer 110 is, for example, formed from a GeₓTe₁₋ₓ alloy (where 0<x<1), for example GeTe, doped or undoped, with the aforementioned elements.

The active layer 110 may have a thickness of between 1 nm and 1 μm. It may have lateral dimensions, for example a width and a length or a diameter of between 1 nm and 10 nm.

In some cases, the Schottky barrier formed at the interface between the active layer 110 and the cathode 120 may completely disappear for one state of ferroelectric bias 111 or be enhanced for another state of ferroelectric bias 111. Thus, for two bias states 111, the nature of the main contact between the active layer 110 and the cathode 120 changes from a Schottky barrier to an ohmic contact. The work function φ₁₂₀ of the cathode 120 is advantageously chosen so that the contact between the active layer 110 and the cathode 120 changes in nature for two bias states 111.

The nature of the material forming the cathode 120 is of great importance because it enables or not a Schottky contact to be formed. Indeed, the work function φ₁₂₀ of the cathode 120 should be chosen as a function of the electron affinity χ₁₁₀ and the band gap Δ₁₁₀ of the active layer 110. In particular, the work function φ₁₂₀ should be chosen according to:

$${χ}_{110} < {ϕ}_{120} < {χ}_{110} + {Δ}_{110}$$

In one embodiment, compatible with the examples described below, the cathode 120 may be metallic. It may also be formed by a degenerate or non-degenerate semiconductor. In the case where it is metal, it is formed, for example, from transition metals, post-transition metals, materials from columns I and II of the periodic table, or an alloy of these metals or materials. The cathode 120 is, for example, made from Li, Be, Mg, Ca, Sr, Ba, Ra, Ti, Zr, Hf, Rf, V, Nb, Ta, Db, Cr, Mo, W, Sg, Mn, Tc, Re, Bh, Fe, Ru, Os, Hs, Co, Rh, Ir, Ni, Pd, Pt, Cu, Ag, Au, Zn, Cd, Hg, Al, Ga, In, Sn, Bi or At. Preferably, the cathode 120 is formed from Au, Pt, Pd or Fe.

In one embodiment, compatible with the embodiments described above, the anode 130 forms an ohmic contact with the active layer 110. Thus, its resistance does not vary as a function of the ferroelectric bias 111 of the active layer 110 and does not influence the on/off ratio. The choice of the material forming the anode 130 ensures ohmic contact with the active layer 110. The work function φ₁₃₀ of the anode 130 should be chosen as a function of the electron affinity χ₁₁₀ and the band gap Δ₁₁₀ of the active layer 110. The work function φ₁₃₀ should be chosen so that:

$${ϕ}_{130} < {χ}_{110} \\ or \\ {ϕ}_{130} > {χ}_{110} + {Δ}_{110}$$

The anode 130 may be formed from one of the aforementioned materials, provided that the above inequalities are satisfied. Stated differently, the anode 130 is, for example, formed from transition metals, or from post-transition metals, or from materials from columns I and II of the periodic table, or from an alloy of these metals or materials. The anode 130 is, for example, made from Li, Be, Mg, Ca, Sr, Ba, Ra, Ti, Zr, Hf, Rf, V, Nb, Ta, Db, Cr, Mo, W, Sg, Mn, Tc, Re, Bh, Fe, Ru, Os, Hs, Co, Rh, Ir, Ni, Pd, Pt, Cu, Ag, Au, Zn, Cd, Hg, Al, Ga, In, Sn, Bi or At. Preferably, the anode 130 is formed from Ti or Ag.

Alternatively, the anode 130 may be semiconducting. Thus, it may form a junction with the active layer 110. For example, it forms a heterojunction with the active layer 110, for example for an anode 130 of Si and an active layer 110 of GeTe. The anode 130 can also form a homojunction with the active layer, for example when the anode 130 and the active layer 110 are of In₂Se₃ but doping within these layers varies. The homojunction can then form a PN-type junction. The element has a diode characteristic for all bias states of the active layer 110.

In one embodiment, the anode 130 is a stack of two semiconducting sub-layers, a first sub-layer being undoped and a second sub-layer being doped. The junction (heterojunction or homojunction, for example, PN) is then formed between the doped semiconducting sub-layer and the active layer 110.

In an alternative embodiment, the anode 130 forms a secondary contact with the active layer 110. This contact can be formed by bringing the anode 130 into direct contact with the active layer 110. Similarly to the main contact, the resistance of the secondary contact is preferably a strictly monotonic function of the ferroelectric bias 111. This strictly monotonic dependence can, for example, be obtained when the ferroelectric bias 111 has a transverse component (that is, a component normal to the interface between the active layer 110 and the anode 130).

Forming the secondary Schottky contact aims at improving on/off ratio of the memory 100. For this, it is preferable for the main and secondary contacts to positively contribute to each other. Indeed, the total resistance of the memory 100 comprises the sum of the resistances of the main and secondary contacts. Thus, it is expected that for a given ferroelectric bias (for example, upwards in FIGS. 1 and 2), the resistances of the main and secondary contacts will be maximal. And for another given ferroelectric bias (for example, downwards in FIGS. 1 and 2), the resistances of the main and secondary contacts will be minimal.

Considering a simple case where the resistance variations of the two Schottky contacts are the same for two distinct states, the on/off ratio becomes:

$$α = \frac{2 {R}_{OFF} + {R}_{110}}{2 {R}_{O N} + {R}_{110}}$$

Thus, the resistance of the main contact as a function of the ferroelectric bias 111 and the resistance of the secondary contact as a function of the ferroelectric bias 111 have two monotony trends, the two trends being opposite to each other. In other words, if the derivative of the resistance of the main contact as a function of bias is strictly positive, then the derivative of the resistance of the secondary contact as a function of bias is strictly negative. For example, if the resistance of the main contact is strictly increasing as a function of the ferroelectric bias, the resistance of the secondary contact is strictly decreasing as a function of the ferroelectric bias.

The embodiment of FIG. 2 differs from the embodiment of FIG. 1 in that the memory comprises an insulating layer 140, ferroelectric or not, disposed between the active layer 110 and the anode 130. The insulating layer 140 can be seen as a tunable resistance, allowing the minimal resistance of the memory 100 to be tuned. The addition of this resistance has little effect on the total resistance when the resistance of the main contact (or main and secondary contacts) is maximal. This insulating layer 140 also facilitates application of a voltage to the active layer 110 (known as the “write voltage”) to switch the ferroelectric bias 111 from one state to another. The insulating layer 140 can also limit diffusion of species to the active layer 110 or from the active layer 110, or modulate charge trapping at the interface between the active layer 110 and the insulating layer 140 or between the insulating layer and the anode and/or cathode.

The insulating layer is, for example, of HfO₂, Al₂O₃, SiN, PZT, BFO or BTO. It has a thickness of between 0.1 nm and 10 nm.

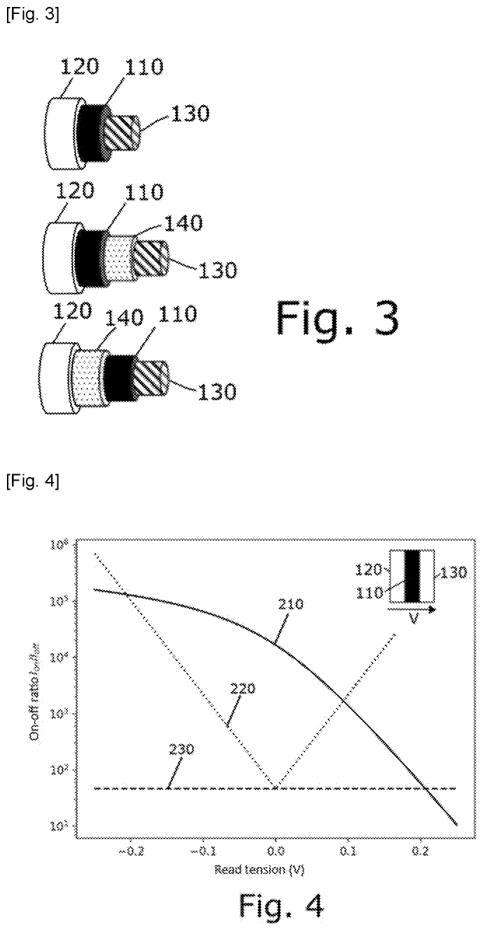

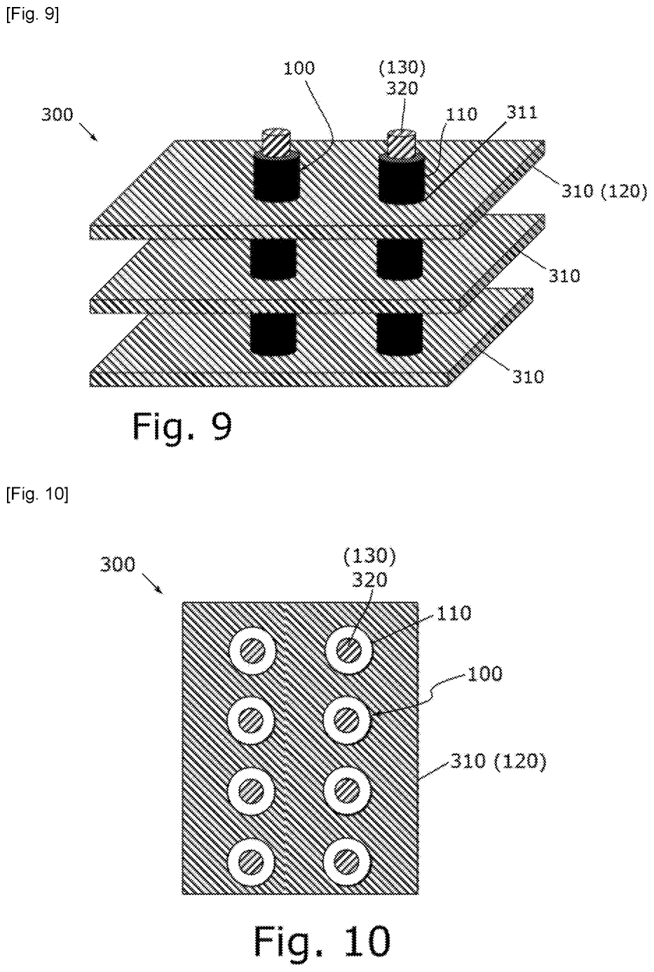

FIG. 3 partially shows three embodiments of the memory 100 according to the invention. In these embodiments, the active layer 110 and the anode 130 are cylindrical. The active layer 110 is wound around the anode 130 like a sheath around a core. The cathode 120 may also be cylindrical and surround the active layer 110. Alternatively, the active layer 110 could surround the cathode 120 instead of surrounding the anode 130. Still alternatively, the cathode 120 is only in contact with a portion, annular or not, of the active layer 110 (see, for example, the embodiment of FIGS. 9 and 10).

In two of the illustrated embodiments, the memory 100 comprises an insulating layer 140 such as described in FIG. 2. The insulating layer 140 is also cylindrical and is inserted between the active layer 110 and the anode 130 or between the active layer 110 and the cathode 120.

FIG. 4 shows three curves 210, 220, 230 corresponding to the on/off ratio measured as a function of an applied voltage known as the “read voltage”. The first on/off curve 210, in a solid line, is an example of the on/off ratio measurable at the terminals of a memory 100 according to the invention. The two other curves 220 and 230, in dashed lines, are measurable at the terminals of memories according to prior art. An insert shows the direction of application of the read voltage V to the memory (100). When the read voltage V applied is positive, the memory 100 is forward biased, that is, the voltage is higher on the anode 130 than on the cathode 120. When the read voltage applied is negative, the memory 100 is reverse biased, that is, the voltage is higher on the cathode 120 than on the anode 130.

The second on/off curve 220 corresponds to a symmetrical memory. That is, a memory having two contacts, respectively between the cathode and the active layer 110 and between the anode 130 and the active layer 110, which can switch from Schottky to ohmic and vice versa, depending on the state of the ferroelectric bias. While the second characteristic 220 shows a high on/off ratio for a high read voltage, it is however minimal around 0 V. The on/off ratio is therefore low for low read voltages.

The third curve 230 corresponds to a memory in which the contact between the cathode 120 and the active layer 110 is a Schottky-type contact the resistance of which varies as a function of the ferroelectric bias state. In this memory, the contact between the anode 130 and the active layer 110 is ohmic and does not vary as a function of the ferroelectric bias. The on/off ratio remains constant, regardless of the read voltage applied. However, the on/off ratio remains low, even for high read voltages.

The first characteristic 210 corresponds to a memory in which the contact between the cathode and the active layer is of the Schottky type in the off state and of the ohmic type in the on state. The difference in contact type between the two states induces an asymmetrical variation. In particular, it exhibits a better on/off ratio when reverse biased. Additionally, the on/off ratio is not reduced around 0 V. Thus, the memory according to the invention exhibits a high on/off ratio even for low read voltages. This is especially true when the memory is reverse biased. For example, the on/off ratio is close to 10⁵ at −0.1 V.

Thus, reading a memory 100 according to the invention can be carried out by applying a voltage, known as the “read voltage”, to the memory in order to reverse bias the memory 100 (that is, with a higher voltage on the cathode than on the anode). Since the conductivity of the active layer 110 is high, and depends little, if at all, on the ferroelectric bias 111, applying the read voltage to the memory 100 amounts to applying said read voltage to the main contact. It is therefore the contact that is reverse biased.

In order to reduce the power consumption of the memory 100, while providing a high on/off ratio, the read voltage of the memory 100 is preferably less than 0.1 V and preferably less than 0.01 V.

The on/off curves of FIG. 4 have been obtained by simulating three memories such as described. The parameters considered comprise a work function of the cathode φ₁₂₀=0.5 eV; a work function of the active layer φ₁₁₀=0.4 eV; a contact surface area between the cathode and the active layer S=2.5 μm²; a resistance for the active layer 110 of R=100Ω; and a temperature T=300 K.

Mechanisms of electron conduction through the Schottky barrier especially comprise field emission, Schottky emission and thermionic emission. In the latter case, the effective Richardson constant considered is A=200 A cm⁻² K⁻².

When manufacturing a memory 100 according to the invention, the formation of the cathode 120 can be carried out on the active layer 110 using nanomanufacturing techniques derived from the so-called CMOS (Complementary Metal Oxide Semiconductor) technology. The cathode 120 is, for example, lithographed or etched or deposited by evaporation or sputtering.

Physical or geometric properties of the memory 100 may be adapted to meet specific operational restrictions. For example, a maximal resistivity of the active layer 100 (and therefore of the memory 100 in the low state) may be required. For this, the manufacture of the memory 100 may provide an optimisation step aimed at adapting physical or geometric properties of the memory 100.

For example, minimising the following equation:

$$U = αρ {( \frac{{I}_{r}}{S} )}^{2} {τ}_{r} + ( 1 - α ) \frac{{E}_{w}^{2}}{ρ} {τ}_{w}$$

with a targeted resistivity ρ, an energy volume density U, a read/write ratio (alpha characterises the usage profile of the memory), a write voltage E_{w}, a read current Iᵣ, a write time τ_{w}, a read time τᵣ, and a surface area S between the cathode 120 and the active layer 110, can achieve optimal resistivity.

Assuming that the influence of doping on the write voltage E_{w} and on the read current Iᵣ is negligible, the optimal targeted resistivity is:

$$ρ = \frac{{E}_{w} S}{{I}_{r}} \sqrt{\frac{{τ}_{w} ( 1 - α )}{{τ}_{r} α}}$$

The targeted resistivity ρ can also be chosen to be minimal in order to maximise the on/off ratio. Indeed, since the resistance in the high-resistance state is dominated by the Schottky contact and the low-resistance state is ohmic, minimising the resistivity ρ will reduce the total resistance of the low-resistance state without affecting the resistance of the high-resistance state. The on/off ratio is therefore improved.

A memory 100 according to the invention can be implemented for a storage application, or for Boolean algebra, especially for in-memory computing, or for artificial intelligence, for example as a synapse in an artificial neural network.

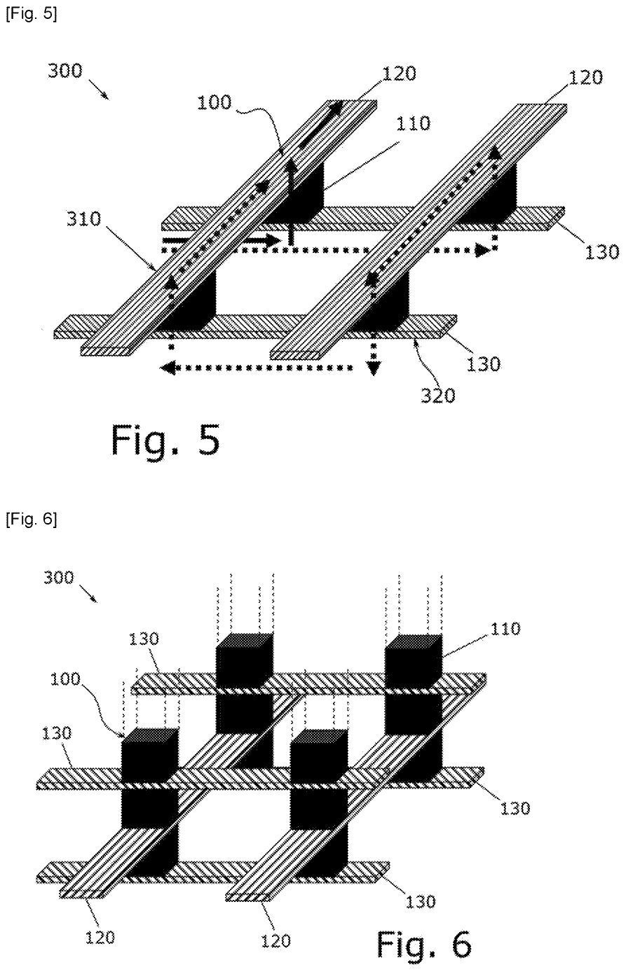

To this end, FIGS. 5 to 10 show different embodiments of a memory array 300 according to the invention, enabling information storage to be performed and memories to be linked to make logical calculi in the memories 100.

The array 300 especially comprises a plurality of memories 100 and a connection architecture allowing each memory 100 to be independently addressed. In the examples illustrated, the connection architecture is of the “crossbar” type. A crossbar architecture comprises a plurality of conductive rows 310 and a plurality of conductive columns 320, intersecting each other. These rows and columns 310, 320 take the form, for example, of metal tracks. Each memory 100 is connected to one of the conductive rows 310 and one of the conductive columns 320 and is preferably disposed at the intersection between said conductive row 310 and said conductive column 320. In this way, applying a voltage between the conductive row 310 and the conductive column 320 allows the memory 100 located at the intersection to be biased. Thus, each memory 100 can be addressed independently of the other memories. The connection of the memories 100 according to this architecture forms an array arrangement.

In FIG. 5, the rows 310 are arranged in parallel to each other. The columns 320 are also arranged in parallel to each other. The rows 310 are disposed in a first plane and the columns 320 are disposed in a second plane, distinct from and parallel to the first plane. The rows 310 and columns 320 intersect, forming right angles in projection. Each memory 100 is disposed at this intersection, joining the first plane to the second plane.

In a crossbar architecture, several memories 100 (at least two) are connected to a same row 310 and several other memories 100 (also at least two) are connected to a same column 320. Thus, applying an electric voltage between a row 310 and a column 320 can induce currents flowing in the memories 100 that are not connected at the intersection of the row and the column. These currents form leakage currents. FIG. 5 shows, in solid lines, a current induced by the application of a potential between a row 310 and a column 320. FIG. 5 shows, in dotted lines, a leakage current that can pass through several rows 310, columns 320 and memories 100.

By virtue of the primary and secondary contacts between, respectively, the cathode 120 and the active layer 110 and the anode 130 and the active layer, the connected memories 100 can operate as Schottky diodes. Unlike standard Schottky diodes, the resistance level of the diode varies as a function of its ferroelectric bias. Connecting memories 100 operating as Schottky diodes makes it possible to drastically reduce the flow of leakage currents. Indeed, the memories 100 the ferroelectric bias of which induces a Schottky contact at their two contacts have high impedance whether they are in the high or low state. Thus, they always have high impedance.

The array 300 may comprise normally off monostable or bistable devices, forming selectors. Each selector is then connected in series to one of the memories 100. The selectors normally have a high impedance, blocking the flow of currents, except in the memory connected to the row and the column to which the read (or write) voltage is applied. Even when they are on, the selectors can have a significant impedance. The large variation in impedance of the memories 100 according to the invention (which especially corresponds to the on/off ratio of the memories) makes it measurable, even in series with a selector having a large impedance.

The formation of a heterojunction or homojunction (for example, of the PN type) between the active layer 110 and the anode 130 (described with reference to FIGS. 1 and 2) makes it possible to integrate the selector function into each memory 100.

In one embodiment, the rows 310 and columns 320 of the array 300 form the cathodes 120 and anodes 130, respectively, of the memories 100 which they connect. Indeed, the materials used to make the rows 310 and columns 320 are perfectly likely to form the rows and columns of a crossbar architecture. Thus, it is not necessary to provide several levels for the cathodes and anodes and for the rows and columns. The array 300 therefore has a reduced overall size.

FIG. 6 shows an embodiment of the array 300 where, unlike the array 300 in FIG. 5, it comprises several pluralities of rows and columns intersecting on several levels so as to form stacks of memories 300. This type of architecture is known as a “3D crossbar” because it also takes advantage of a third dimension of the space to stack the array layers and reduce the lateral overall size of the array 300.

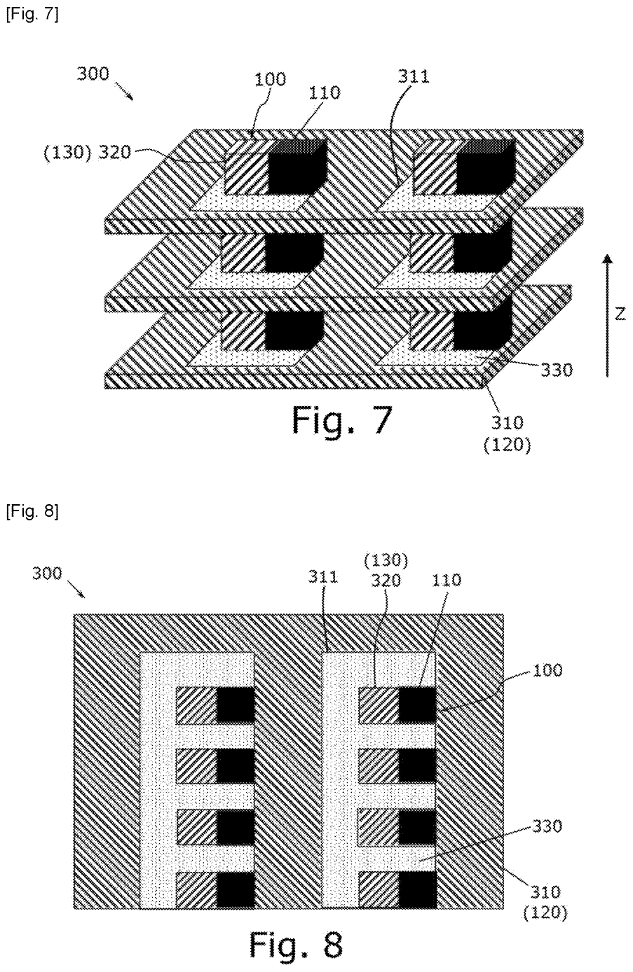

FIGS. 7 and 8 show two other embodiments of the array 300 in a perspective view and a top view. These arrays 300 differ from FIG. 5 in that the columns 320 vertically extend (the vertical being represented by the axis Z) and in that the rows 310 form layers or plates, vertically arranged one above the other. Openings 321, provided in each row 310, allow the columns 320 to pass through the rows. To connect each memory 100 to a column 320 and a row 310, said memory 100 extends, for example, against at least a portion of the column 320 and against an edge of the opening 311 provided in the row.

Advantageously, in this embodiment, the rows 310 and columns 320 also form the cathodes 120 and anodes 130 of the memories 100. Even more advantageously, and as set forth in FIG. 7, a plurality of memories 100 connected to a same column 320 share the same active layer 110. The active layer 110 extends against the column 320, over the entire height of the column 320. Each memory 100 is then located at an intersection between the column 320 and one of the rows 310. In order to avoid any interference between the memories 100, the rows 310 are spaced apart by a distance greater than a ferroelectric domain length of the active layer 100 and preferably greater than ten times the ferroelectric domain length of the active layer 100. By “ferroelectric domain length”, it is meant a characteristic dimension of a ferroelectric domain (such as its diameter). This domain length is, for example, between a few nanometres and a few tens of nanometres.

An insulating element 330 disposed in the opening 311 of each row 310 ensures mechanical support, by allowing a contact to be kept between the active layer 110 and the edge of each opening 311. This insulating element 330 also insulates the column 320 and the row 310.

The embodiments of FIGS. 7 and 8 differ from that of FIG. 6 in that they include the possibility of a ferroelectric material with out-of-plane ferroelectric bias (for FIG. 6) and in-plane ferroelectric bias (for FIGS. 7 and 8). By “out-of-plane”, it is meant bias in a direction perpendicular to the plane of the substrate, and by “in-plane”, bias along a direction in the plane of the substrate.

The embodiments of FIGS. 9 and 10 show two other embodiments of the array 300 in a perspective view and a top view. These embodiments correspond to a ferroelectric material with in-plane bias. These arrays 300 combine the embodiments of FIGS. 7 and 8 and FIG. 3. Indeed, for these arrays as well, the rows 310 and columns 320 form the cathodes 120 and anodes 130 of the memories 100. In these embodiments, the columns 310 are cylindrical. The active layer 110, common to a plurality of memories 100, is also cylindrical and surrounds the column 320. The active layer 110 is in contact with the entire opening 311 through which the column 320 and the active layer 110 pass. The row 310 is therefore in contact with an annular portion of the active layer 110.

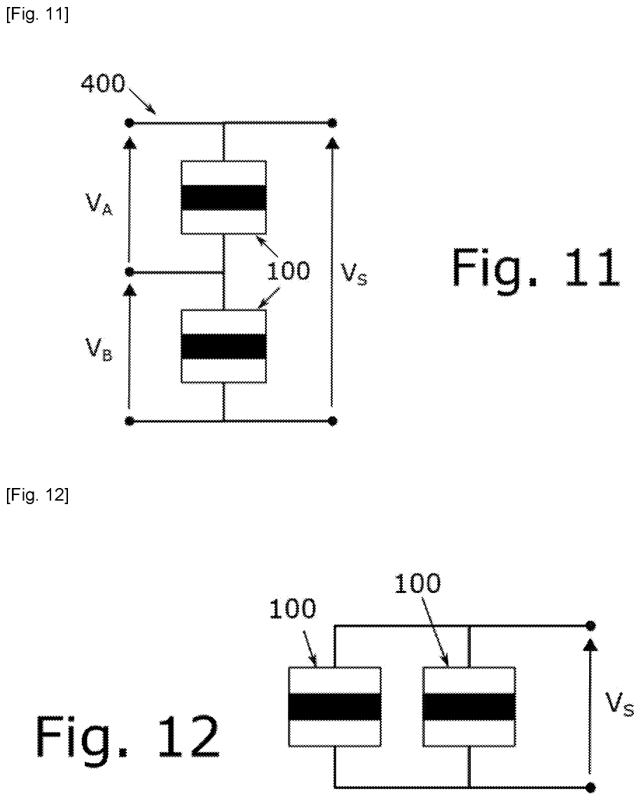

FIGS. 11 and 12 show two memory assemblies for making an OR logic gate and an AND logic gate, respectively.

The OR logic gate (FIG. 11) corresponds to two memories connected in series. The total impedance of this chain of memories 100 will then be high impedance if one of the memories 100 is high impedance. The impedance will be low if all the memories 100 are low impedance. By acting on the ferroelectric bias of each memory, it is then possible to perform a binary OR operation. Connecting at least three memories in series allows an OR logic operation to be performed on at least three inputs.

The AND logic gate (FIG. 12) corresponds to two memories connected in parallel. The total impedance of this chain of memories 100 will then be high impedance if all the memories 100 are of high impedance. The total impedance will be low impedance if at least one of the memories 100 is of low impedance. Connecting at least three memories in parallel allows an AND logic operation to be performed on at least three inputs.

1. A memory comprising:
a main conductive electrode forming a cathode;
a secondary conductive electrode forming an anode; and
a ferroelectric semiconducting layer forming an active layer, disposed between the cathode and the anode, the active layer having a ferroelectric bias with a plurality of stable states,
the cathode forming a main contact with the active layer, the resistance of the main contact strictly monotonically varying as a function of the ferroelectric bias, the behaviour of the main contact forming, as a function of the ferroelectric bias:
an ohmic contact for a first stable state of the plurality of stable states; and
a Schottky contact for at least a second stable state of the plurality of stable states, the active layer being degenerate and having an energy band gap of less than 1.5 eV.

2. The memory according to claim 1, wherein the main contact also forms a Schottky contact for a third stable state of the plurality of stable states, the resistance of the main contact for the second stable state being lower than the resistance of the main contact for the third stable state.

3. The memory according to claim 1, wherein the main contact is formed at an interface between the active layer and the cathode, and wherein, for each stable state, the ferroelectric bias has, at said interface, a component normal to said interface.

4. The memory according to claim 1, wherein the anode forms an ohmic contact with the active layer, the resistance of the ohmic contact being independent of the ferroelectric bias.

5. The memory according to claim 1, wherein the anode forms a secondary contact with the active layer, the resistance of the secondary contact strictly monotonically varying as a function of the ferroelectric bias, the resistance of the main contact as a function of the ferroelectric bias having a first monotony trend and the resistance of the secondary contact as a function of the ferroelectric bias having a second monotony trend, the two monotony trends being opposite to each other.

6. The memory according to claim 1, wherein the stack comprises an insulating layer disposed between the active ferroelectric layer and the cathode or between the active layer and the anode.

7. The memory according to claim 1, characterised in that the active ferroelectric layer is of GeTe.

8. The memory according to claim 7, wherein the active ferroelectric layer of GeTe is co-doped with Bi and Cu, co-doped with Pb and Bi, or doped with Sn, Cu or Sb.

9. The memory according to claim 7, wherein the material of the cathode is selected from one of the following materials: Pt, Pd, Au, Fe.

10. The memory according to claim 7, wherein the material of the anode is selected from one of the following materials: Ti, TiN, Ag.

11. The memory according to claim 1, wherein the material of the anode is a semiconductor material so as to form a junction with the active layer such as a heterojunction or a homojunction.

12. The memory according to claim 11, wherein the junction is a homojunction forming a PN-type junction.

13. The memory according to claim 1, wherein the cathode is made from a material selected from: transition metals or transition metal alloys, post-transition metals or post-transition metal alloys, materials from columns I and II of the periodic table, or alloys of these materials.

14. The memory according to claim 1, wherein the active layer is cylindrical and is wound around the cathode or around the anode.

15. A reading of the memory according to claim 1, wherein the Schottky contact is reverse biased.

16. A method for manufacturing the memory according to claim 1, comprising:
minimising an energy volume density U:
$$U = αρ {( \frac{{I}_{r}}{S} )}^{2} {τ}_{r} + ( 1 - α ) \frac{{E}_{w}^{2}}{ρ} {τ}_{w}$$
with a resistivity ρ, a read/write ratio α, a write voltage E_{w}, a read current Iᵣ, a write time τ_{w}, and a read time τᵣ, and a surface area S, so as to obtain an optimal resistivity; and
forming a cathode, an anode and an active layer so that the active layer is disposed between the cathode and the anode and so that the active layer has a ferroelectric bias having a plurality of stable states, and so that the cathode forms a main contact with optimal surface area S with the active layer, the resistance of the main contact strictly monotonically varying as a function of the ferroelectric bias, the behaviour of the main contact forming, as a function of the ferroelectric bias an ohmic contact for a first stable state of the plurality of stable states; and a Schottky contact for at least a second stable state of the plurality of stable states, the active layer being degenerate and having an energy band gap of less than 1.5 eV.

17. A memory array comprising:
a plurality of memories according to claim 1;
a plurality of conductive rows; and
a plurality of conductive columns,
for each memory, the cathode is formed by one of the conductive rows and the anode is formed by one of the conductive columns.

18. The array according to claim 17, wherein the conductive rows are parallel to each other, the conductive columns are parallel to each other, the conductive rows and the conductive columns being arranged to intersect, each memory being disposed at an intersection between one of the conductive rows and one of the conductive columns.
